(19) United States
(12) Patent Application Publication
(10) Pub. No.: US 2023/0232612 A1
(43) Pub. Date: Jul. 20, 2023

(54) Semiconductor Devices

(71) Applicant: Samsung Electronics Co., Ltd., Suwon-si (KR)

(72) Inventors: Chanwoo Shin, Seoul (KR); Hyuckjin KANG, Seoul (KR); Donghwan LEE, Daejeon (KR); Jeonil LEE, Suwon-si (KR); Minwu KIM, Hwaseong-si (KR); Jungwoo SONG, Hwaseong-si (KR)

(73) Assignee: Samsung Electronics Co., Ltd., Suwon-si (KR)

(21) Appl. No.: 18/050,179

(22) Filed: Oct. 27, 2022

(30) Foreign Application Priority Data
Jan. 18, 2022 (KR) 10-2022-0007026

(51) Int. Cl. H01L 29/94

(52) U.S. Cl. CPC H01L 27/10814; H01L 27/10885; H01L 27/10855

(57) ABSTRACT

A semiconductor device includes a bit line structure on a substrate, a lower contact plug on a portion of the substrate adjacent to the bit line structure, an upper contact plug including a first metal pattern on the lower contact plug and a second metal pattern contacting an upper surface and an upper sidewall of the first metal pattern, and a capacitor on the upper contact plug. The upper surface of the first metal pattern is above an upper surface of the bit line structure with respect to an upper surface of the substrate.

### CROSS-REFERENCE TO RELATED APPLICATION

This application claims priority under 35 U.S.C. § 119 to Korean Patent Application No. 10-2022-0007026 filed on Jan. 18, 2022 in the Korean Intellectual Property Office, the disclosure of which is hereby incorporated by reference in its entirety.

### BACKGROUND

Some example embodiments relate to a semiconductor device. For example, some example embodiments relate to a DRAM device.

When a DRAM device is manufactured, lower contact plugs may be formed between bit line structures, an upper contact plug layer may be formed on the lower contact plug, and an upper portion of the upper contact plug layer may be partially etched to form upper contact plugs serving as land pads for capacitors.

As the integration degree of the DRAM device increases, distances between the bit line structures may decrease, and thus the process margin for etching the upper contact plug layer to form the upper contact plugs may decrease.

### SUMMARY

Some example embodiments provide a semiconductor device having improved characteristics.

According various example embodiments, there is a semiconductor device. The semiconductor device may include a bit line structure on a substrate, a lower contact plug on a portion of the substrate and adjacent to the bit line structure, an upper contact plug including a first metal pattern on the lower contact plug and a second metal pattern contacting an upper surface of and an upper sidewall of the first metal pattern, and a capacitor on the upper contact plug. The upper surface of the first metal pattern may be higher than or above an upper surface of the bit line structure with respect to an upper surface of the substrate.

According to various example embodiments, there is a semiconductor device. The semiconductor device may include a bit line structure on a substrate, a lower contact plug on a portion of the substrate and adjacent to the bit line structure, an upper contact plug on the lower contact plug and including a first metal pattern, a barrier pattern covering a lower surface of and a lower sidewall of the first metal pattern, the upper contact plug further including a second metal pattern contacting an upper surface of and an upper sidewall of the first metal pattern and an upper surface of the barrier pattern, and a capacitor on the upper contact plug. The upper surface of the barrier pattern may be planar.

According to some example embodiments, there is a semiconductor device. The semiconductor device may include an active pattern on a substrate, a gate structure buried in an upper portion of the active pattern and extending in a first direction that is parallel to an upper surface of the substrate, a bit line structure on a central upper surface of the active pattern and extending in a second direction that is parallel to the upper surface of the substrate and perpendicular to the first direction, a spacer structure on a sidewall of the bit line structure, a contact plug structure on each of opposite end portions of the active pattern, and a capacitor or other memory structure on the contact plug structure. The contact plug structure may include a lower contact plug, a metal silicide pattern on the lower contact plug, a barrier pattern on the metal silicide pattern, a first metal pattern of which a lower surface and a lower sidewall are covered by the barrier pattern, and a second metal pattern contacting an upper surface and an upper sidewall of the first metal pattern and upper surfaces of the bit line structure and the spacer structure. The upper surface of the first metal pattern may be higher than or above the upper surface of the bit line structure with respect to an upper surface of the substrate.

In a method of manufacturing the semiconductor device in accordance with various example embodiments, the upper contact plugs electrically connected to the capacitors, respectively, between the bit line structures may be fabricated by forming a lower metal pattern on the lower contact plug and forming an upper metal pattern to contact an upper surface and an upper sidewall of the lower metal pattern through a damascene process. Thus, the upper metal pattern serving a landing pad and the lower metal pattern on the lower contact plug electrically connected to the source/drain region may not be spaced apart from each other but may be well connected to each other.

### BRIEF DESCRIPTION OF THE DRAWINGS

FIGS. 1 to 18 are plan views and cross-sectional views illustrating a method of manufacturing a semiconductor device in accordance with various example embodiments.

FIGS. 19 and 20 are cross-sectional views illustrating a method of manufacturing a semiconductor device in accordance with various example embodiments.

### DETAILED DESCRIPTION

The above and other aspects and features of a semiconductor device and a method of manufacturing the same in accordance with various example embodiments will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer, or section from another region, layer, or section. Thus, a first element, component, region, layer and/or section discussed below could be termed a second or third element, component, region, layer and/or section without departing from the teachings of inventive concepts.

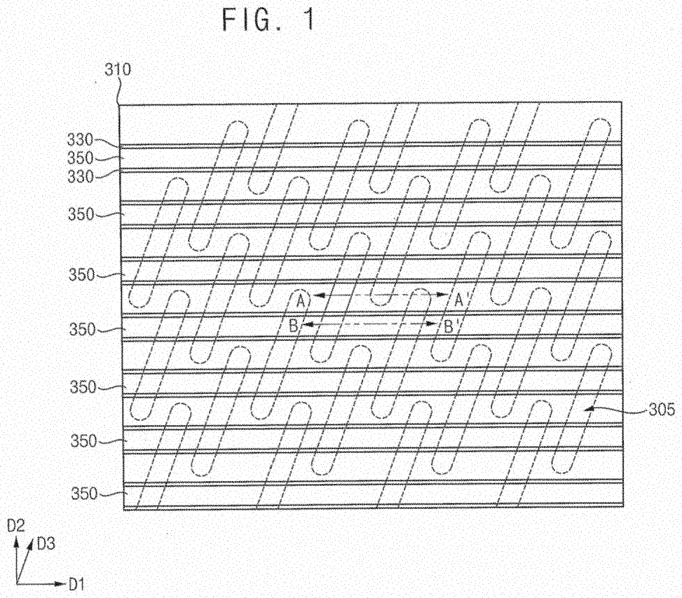

FIGS. 1 to 18 are plan views and cross-sectional views illustrating a method of manufacturing a semiconductor device in accordance with example embodiments.

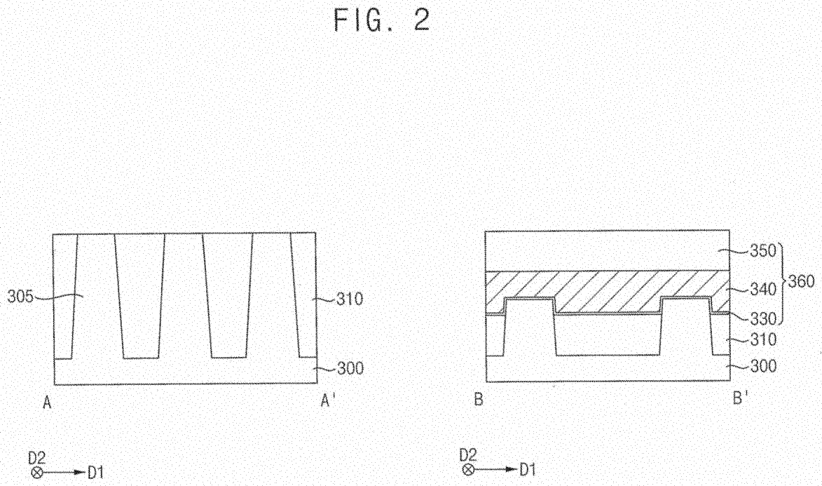

Particularly, FIGS. 1, 3, 6, 10 and 16 are the plan views, and each of FIGS. 2, 4-5, 7-9, 11-15 and 17-18 includes cross-sections taken along lines A-A′ and B-B′ of a corresponding plan view.

Hereinafter, in the specification (and not necessarily in the claims), two directions substantially parallel to an upper surface of a substrate and substantially perpendicular to each other may be referred to as first and second directions D1 and D2, respectively, and a direction substantially parallel to the upper surface of the substrate and having an angle such as an acute angle with respect to one of the first and second directions D1 and D2 may be referred to as a third direction D3.

Referring to FIGS. 1 and 2, an upper portion of a substrate 300 may be removed to form a first recess, and an isolation pattern 310 may be formed to fill or at least partially fill the first recess.

The substrate 300 may include one or more of silicon, germanium, silicon-germanium, or a III-V group compound semiconductor, such as GaP, GaAs, or GaSb. In some example embodiments, the substrate 300 may be a silicon-on-insulator (SOI) substrate or a germanium-on-insulator (GOI) substrate.

As the isolation pattern 310 is formed on the substrate 300, an active pattern 305 of which a sidewall is covered by or conformal with the isolation pattern 310 may be defined. The active pattern 305 may extend in the third direction D3, and a plurality of active patterns 305 may be spaced apart from in the first and second directions D1 and D2. The isolation pattern 310 may include, for example, an oxide such as silicon oxide.

The active pattern 305 and the isolation pattern 310 may be etched or partially etched to form a second recess extending in the first direction D1, and a gate structure 360 may be formed in the second recess. The gate structure 360 may include a gate insulation pattern 330 on a bottom and a sidewall of the second recess, a gate electrode 340 on a portion of the gate insulation pattern 330 on the bottom and a lower sidewall of the second recess, and a gate mask 350 on the gate electrode 340 and filling an upper portion of the second recess.

The gate insulation pattern 330 may include, for example, an oxide such as silicon oxide, the first barrier pattern 130 may include, for example, one or more of a metal, a metal nitride, a metal silicide, doped polysilicon, etc., and the gate mask 350 may include, for example, a nitride such as silicon nitride.

In some example embodiments, the gate structure 360 may extend in the first direction D1, and a plurality of gate structures 360 may be spaced apart from each other in the second direction D2.

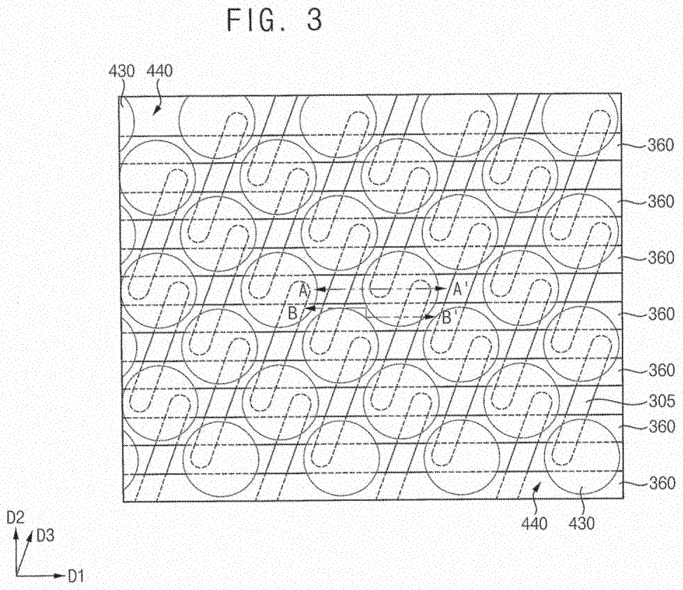

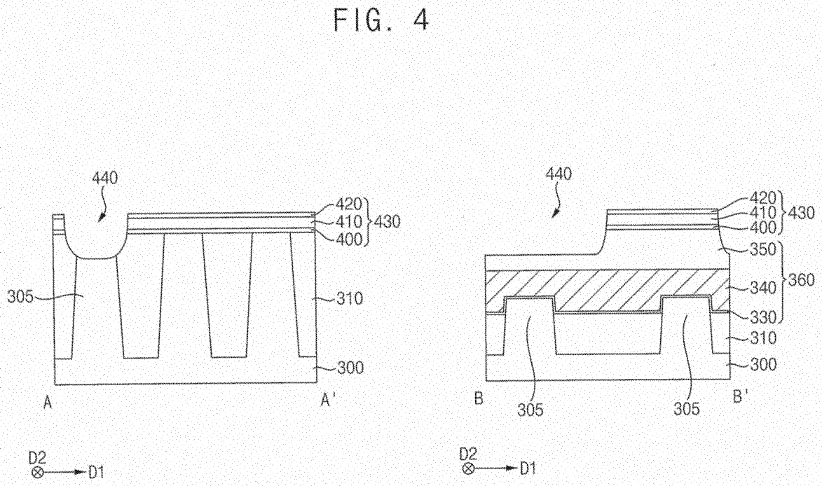

Referring to FIGS. 3 and 4, an insulation layer structure 430 may be formed on the active pattern 305, the isolation pattern 310 and the gate structure 360. The insulation layer structure 430 may include first, second and third insulation layers 400, 410 and 420 sequentially stacked. The first and third insulation layers 400 and 420 may include, for example, an oxide such as silicon oxide, and the second insulation layer 410 may include, for example, a nitride, e.g., silicon nitride.

The insulation layer structure 430 may be patterned, and the active pattern 305, the isolation pattern 310 and the gate mask 350 of the gate structure 360 may etched or be partially etched using the patterned insulation layer structure 430 as an etching mask, so as to form a first opening 440. In some example embodiments, the patterned insulation layer structure 430 may have a shape of a circle and/or an ellipse in a plan view, and a plurality of insulation layer structures 430 may be spaced apart from each other in both the first and second directions D1 and D2. Each of the insulation layer structures 430 may fully or at least partially overlap end portions in the third direction D3 of the active patterns 305 in a vertical direction that is substantially perpendicular to an upper surface of the substrate 300.

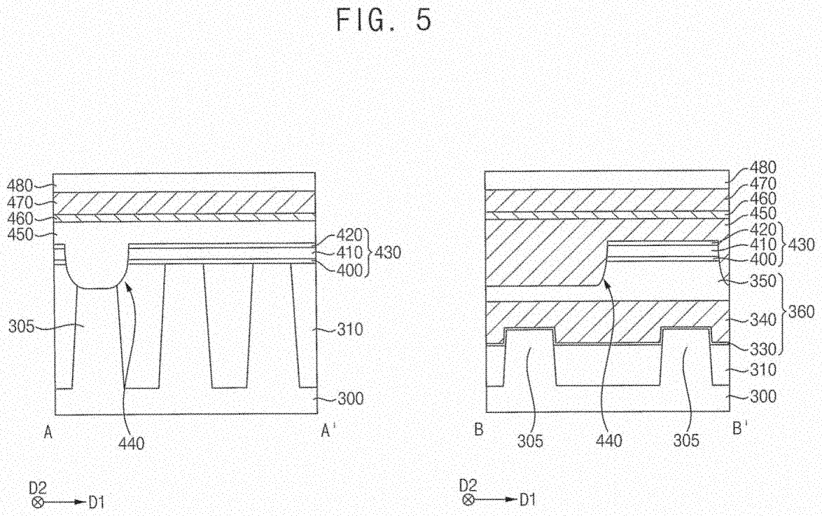

Referring to FIG. 5, a first conductive layer 450, a first barrier layer 460, a second conductive layer 470 and a first mask layer 480 may be sequentially stacked on the insulation layer structure 430, and the active pattern 305, the isolation pattern 310 and the gate structure 360 exposed by the first opening 440, and the first conductive layer 450, the first barrier layer 460 and the second conductive layer 470 may form a conductive layer structure. The first conductive layer 450 may fully or at least partially fill the first opening 440.

The first conductive layer 450 may include, for example, doped polysilicon, the first barrier layer 460 may include, for example, a metal silicon nitride such as titanium silicon nitride, the second conductive layer 470 may include, for example, a metal such as tungsten, and the first mask layer 480 may include, for example, a nitride such as silicon nitride; however, example embodiments are not limited thereto.

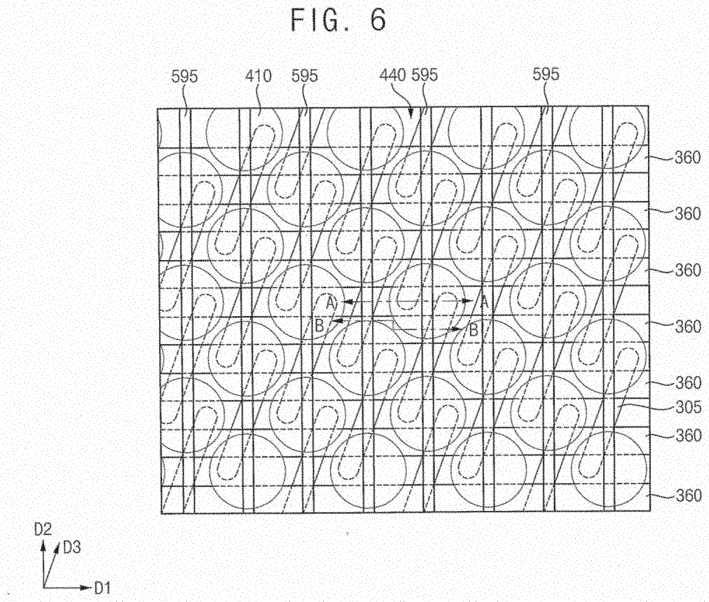

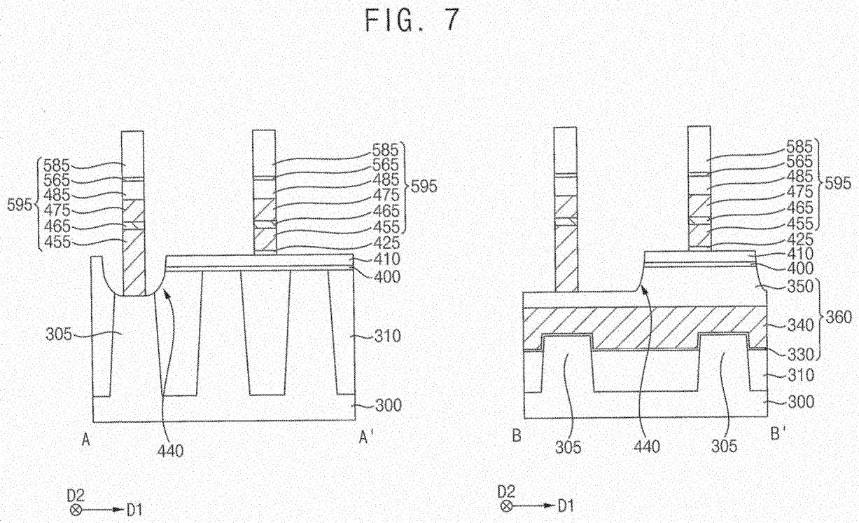

Referring to FIGS. 6 and 7, a first etch stop layer and a first capping layer may be sequentially formed on the conductive layer structure, the first capping layer may be etched to form a first capping pattern 585, and the first etch stop layer, the first mask layer 480, the second conductive layer 470, the first barrier layer 460 and the first conductive layer 450 may be sequentially etched using the first capping pattern 585 as an etching mask.

In some example embodiments, the first capping pattern 585 may extend in the second direction D2, and a plurality of first capping patterns 585 may be spaced apart from each other in the first direction D1.

With the etching process, a first conductive pattern 455, a first barrier pattern 465, a second conductive pattern 475, a first mask 485, a first etch stop pattern 565 and the first capping pattern 585 may be sequentially stacked on the first opening 440, and a third insulation pattern 425, the first conductive pattern 455, the first barrier pattern 465, the second conductive pattern 475, the first mask 485, the first etch stop pattern 565 and the first capping pattern 585 may be sequentially stacked on the second insulation layer 410 of the insulation layer structure 430 at an outside of the first opening 440.

Hereinafter, the first conductive pattern 455, the first barrier pattern 465, the second conductive pattern 475, the first mask 485, the first etch stop pattern 565 and the first capping pattern 585 sequentially stacked may be referred to or collectively referred to as a bit line structure 595. The bit line structure 595 may include a conductive structure including the first conductive pattern 455, the first barrier pattern 465 and the second conductive pattern 475 sequentially stacked, and an insulation structure on the conductive structure and including the first mask 485, the first etch stop pattern 565 and the first capping pattern 585 sequentially stacked on the conductive structure. In some example embodiments, the bit line structure 595 may extend in the second direction D2 on the substrate 100, and a plurality of bit line structures 595 may be spaced apart from each other in the first direction D1.

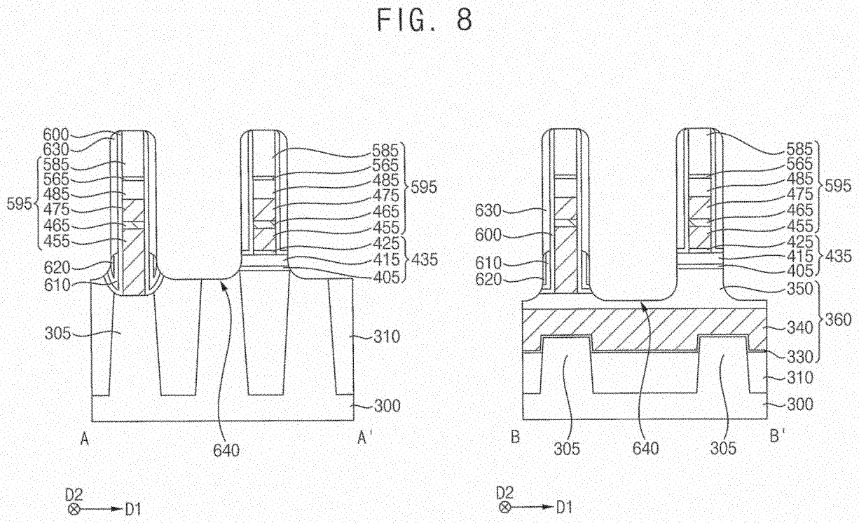

Referring to FIG. 8, a first spacer layer may be formed on the substrate 300 having the bit line structure 595 thereon, and fourth and fifth insulation layers may be sequentially formed on the first spacer layer.

The first spacer layer may also cover a sidewall of the third insulation pattern 425 under a portion of the bit line structure 595 on the second insulation layer 410, and the fifth insulation layer may fill a remaining portion of the first opening 440.

The first spacer layer may include, for example, a nitride such as silicon nitride, the fourth insulation layer may include, for example, an oxide such as silicon oxide, and the fifth insulation layer may include, for example, a nitride such as silicon nitride.

The fourth and fifth insulation layers may be etched by an etching process. In some example embodiments, the etching process may be performed by a wet etching process using one or more or all of phosphoric acid, standard clean one (SC1) and hydrofluoric acid as an etching solution, and other portions of the fourth and fifth insulation layers except for portions of the fourth and fifth insulation layers in the first opening 440 may be removed. Thus, most portion of a surface of the first spacer layer, for example, other portions of the first spacer layer except for the portion thereof in the first opening 440 may be exposed, and the portions of the fourth and fifth insulation layers remaining in the first opening 440 may form fourth and fifth insulation patterns 610 and 620, respectively.

A second spacer layer may be formed on the exposed surface of the first spacer layer and the fourth and fifth insulation patterns 610 and 620 in the first opening 440, and may be anisotropically etched (e.g. with a dry etching process) to form a second spacer 630 on the surface of the first spacer layer and the fourth and fifth insulation patterns 610 and 620 to cover a sidewall of the bit line structure 595. The second spacer layer may include, for example, an oxide such as silicon oxide.

A dry etching process such as a reactive ion etching (RIE) process may be performed using the first capping pattern 585 and the second spacer 630 as an etching mask to form a second opening 640 exposing an upper surface of the active pattern 305, and upper surfaces of the isolation pattern 310 and the gate mask 350 may also be exposed by the second opening 640.

By the dry etching process, a portion of the first spacer layer on the upper surfaces of the first capping pattern 585 and the second insulation layer 410 may be removed, and thus a first spacer 600 may be formed to cover the sidewall of the bit line structure 595. Additionally or alternatively, during the dry etching process, the first and second insulation layers 400 and 410 may be partially removed, and first and second insulation patterns 405 and 415 may remain under the bit line structure 595. The first to third insulation patterns 405, 415 and 425 sequentially stacked under the bit line structure 595 may form an insulation pattern structure.

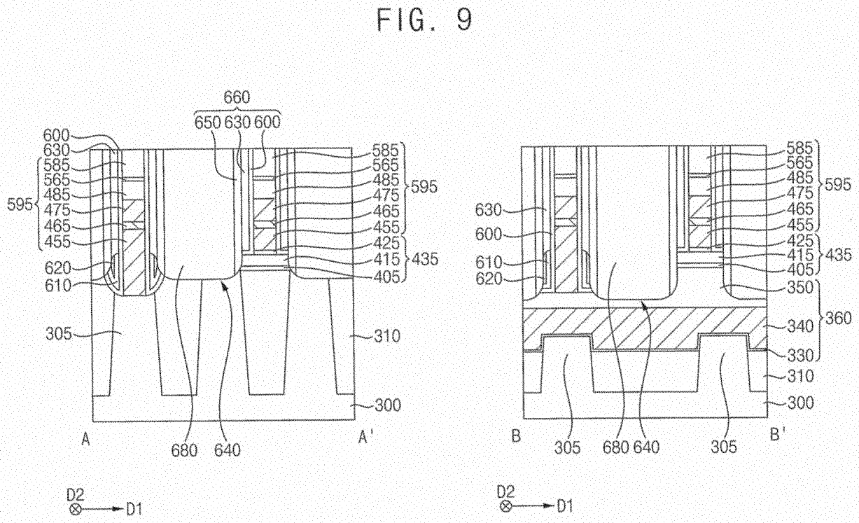

Referring to FIG. 9, a third spacer layer may be formed on the upper surface of the first capping pattern 585, an outer sidewall of the second spacer 630, portions of the upper surfaces of the fourth and fifth insulation patterns 610 and 620, and upper surfaces of the active pattern 305, the isolation pattern 310 and the gate mask 350 exposed by the second opening 640, and may be anisotropically etched (e.g. with a dry etch such as an RIE process) to form a third spacer 650 covering the sidewall of the bit line structure 595. The third spacer layer may include, for example, a nitride such as silicon nitride.

The first spacer 600, the second spacer 630 and the third spacer 650 sequentially stacked on the sidewall of the bit line structure 595 in a horizontal direction substantially parallel to the upper surface of the substrate 300 may be referred to as a spacer structure 660.

A second capping pattern 680 may be formed on the substrate 300 to fill the second opening 640, and an upper portion of the second capping pattern 680 may be planarized until an upper surface of the first capping pattern 585 is exposed. The planarization may be performed with a chemical mechanical planarization (CMP) process and/or with an etch-back process.

In some example embodiments, the second capping pattern 680 may extend in the second direction D2, and a plurality of second capping patterns 680 may be spaced apart from each other in the first direction D1. The second capping pattern 680 may include, for example, a nitride such as silicon nitride.

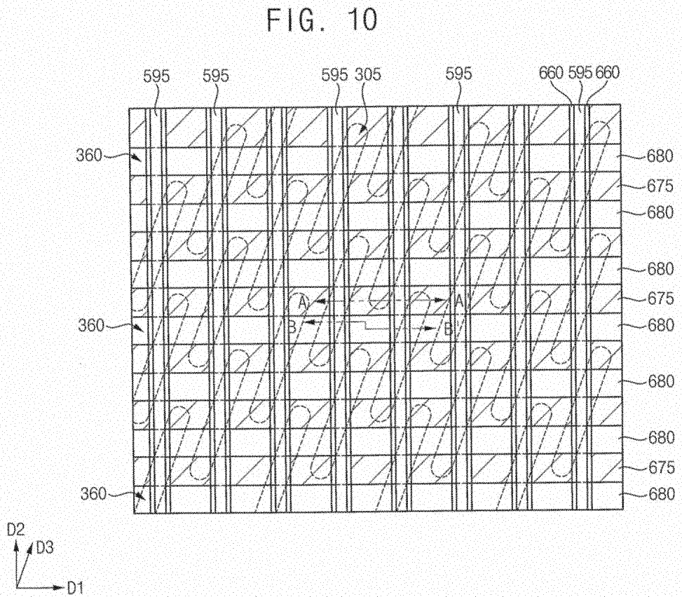

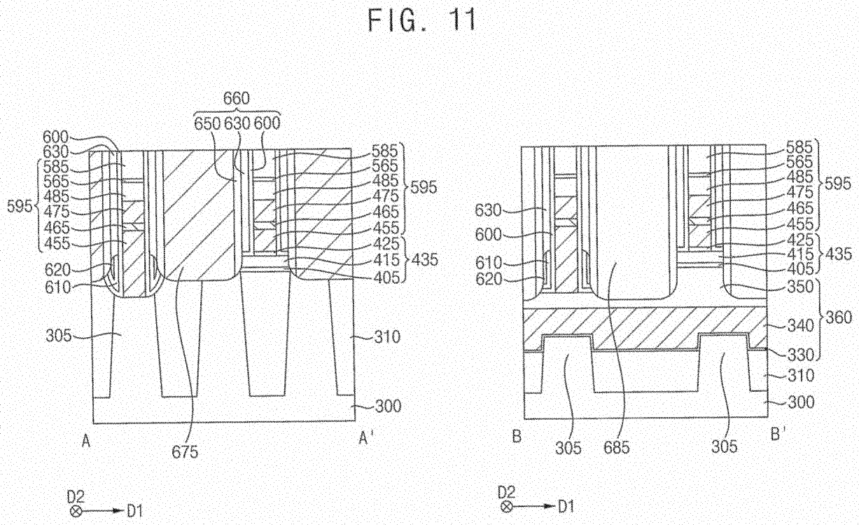

Referring to FIGS. 10 and 11, a second mask having a plurality of third openings spaced apart from each other in the second direction D2, each of which may extend in the first direction D1, may be formed on the first and second capping patterns 585 and 680 and the spacer structure 660, and the second capping pattern 680 may be etched using the second mask as an etching mask.

In some example embodiments, each of the third openings may overlap the gate structure 360 in the vertical direction. By the etching process, a fourth opening exposing an upper surface of the gate mask 350 of the gate structure 360 may be formed between the bit line structures 595.

After removing the second mask, a lower contact plug layer may be formed to fill the fourth opening (e.g. formed with a chemical vapor deposition (CVD) process and/or a sputter deposition process), and an upper portion of the lower contact plug layer may be planarized (e.g. with a CMP process and/or an etch-back process) until upper surfaces of the first and second capping patterns 585 and 680 and the spacer structure 660 are exposed. Thus, the lower contact plug layer may be transformed into a plurality of lower contact plugs 675 spaced apart from each other in the second direction D2 between the bit line structures 595. Additionally or alternatively, the second capping pattern 680 extending in the second direction D2 between the bit line structures 595 may be divided a plurality of parts spaced apart from each other in the second direction D2 by the lower contact plugs 675.

The lower contact plug 675 may include, for example, doped polysilicon; however, example embodiments are not limited thereto.

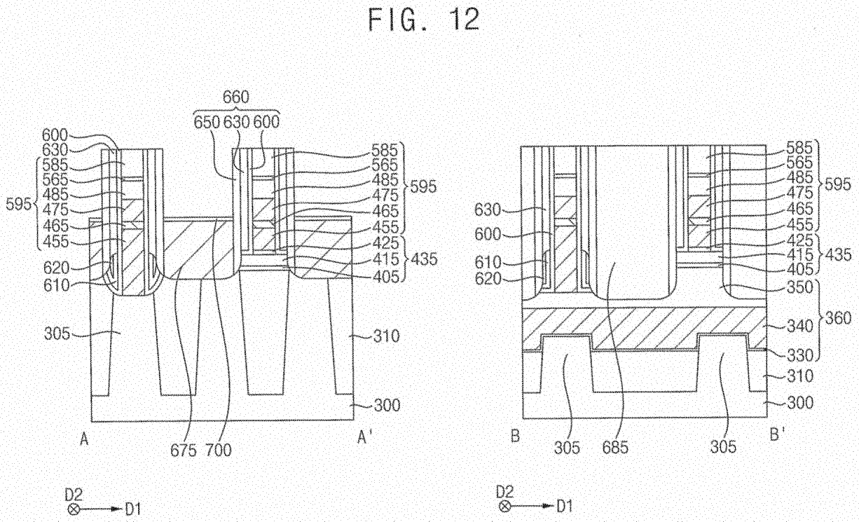

Referring to FIG. 12, an upper portion of the lower contact plug 675 may be removed to expose an upper portion of the spacer structure 660 on the sidewall of the bit line structure 595.

A metal silicide pattern 700 may be formed on an upper surface of the lower contact plug 675. In some example embodiments, the metal silicide pattern 700 may be formed by forming a first metal layer on the bit line structure 595, the spacer structure 660, the second capping pattern 680 and the lower contact plug 675, performing a heat treatment such as a thermal anneal and/or laser anneal and/or rapid thermal anneal (RTA) on the first metal layer to perform a silicidation process in which the first metal layer including a metal and the lower contact plug 675 including silicon are reacted with each other, and removing an unreacted portion of the first metal layer. The metal silicide pattern 700 may include, for example, any or all of cobalt silicide, nickel silicide, titanium silicide, etc.

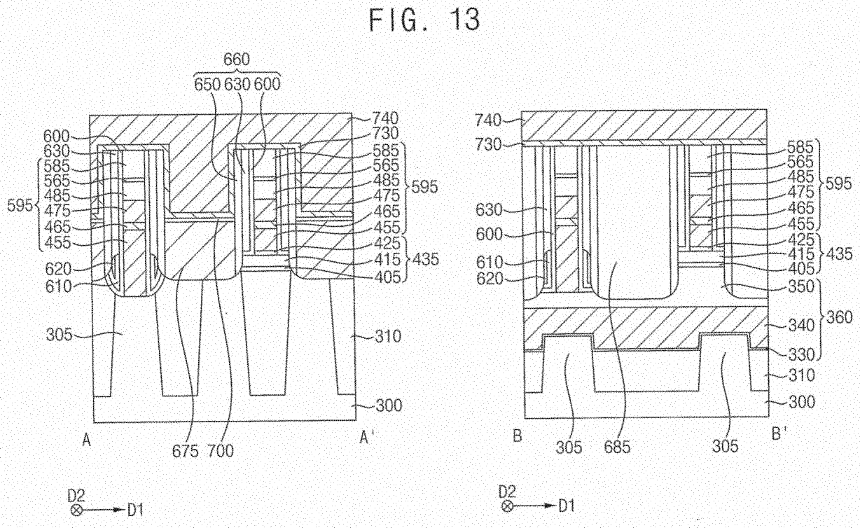

Referring to FIG. 13, a second barrier layer 730 may be formed on the bit line structure 595, the spacer structure 660, the second capping pattern 680 and the metal silicide pattern 700, and a second metal layer 740 may be formed on the second barrier layer 730 to fill a space between the bit line structures 595.

The second barrier layer 730 may include, for example, a metal nitride such as titanium nitride, and the second metal layer 740 may include, for example, a metal such as tungsten.

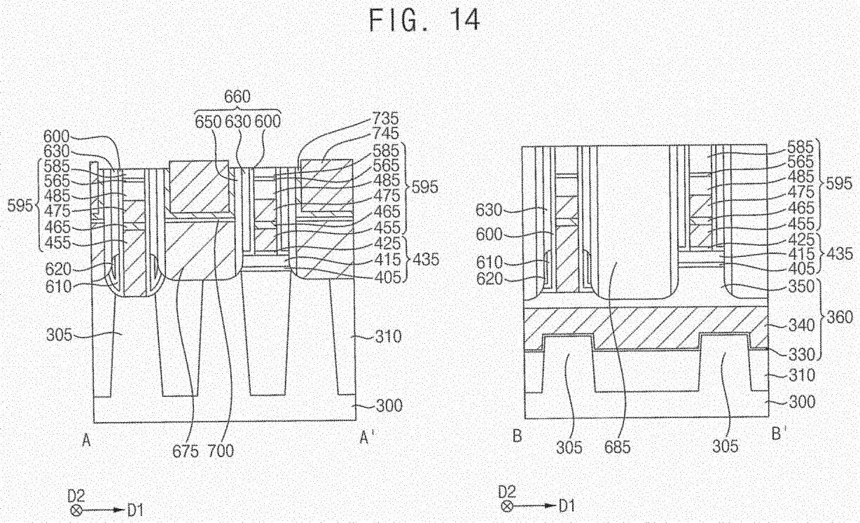

Referring to FIG. 14, a planarization process may be performed on upper portions of the second metal layer 740 and the second barrier layer 730 until upper surfaces of the bit line structure 595, the spacer structure 660 and the second capping pattern 680 are exposed. The planarization process may include a chemical mechanical polishing (CMP) process and/or an etch back process.

By the planarization process, the second metal layer 740 and the second barrier layer 730 may be transformed into a second metal pattern 745 and a second barrier pattern 735, respectively. In some example embodiments, a plurality of second metal patterns 745 may be spaced apart from each other in the first and second directions D1 and D2.

Upper portions of the first and second capping patterns 585 and 680 and the spacer structure 660 and an upper portion of the second barrier pattern 735 adjacent thereto may be removed by, for example, a dry etching process, so that an upper sidewall of the second metal pattern 745 may be exposed. The dry etching process may be performed after the planarization process; however, example embodiments are not limited thereto.

In some example embodiments, the second spacer 630 included in the spacer structure 660 may be removed to form an air gap; however, example embodiments are not limited thereto.

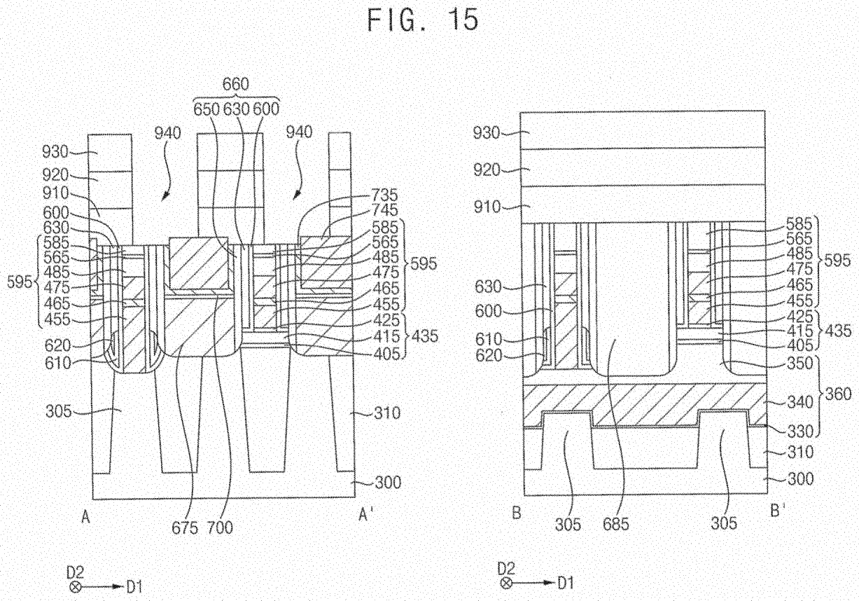

Referring to FIG. 15, first and second insulating interlayers and a third mask layer may be sequentially formed on the bit line structure 595, the spacer structure 660, the second capping pattern 680, the second barrier pattern 735 and the second metal pattern 745.

In some example embodiments, the first insulating interlayer may include, for example, an oxide such as silicon oxide, the second insulating interlayer may include, for example, a nitride such as silicon nitride, and the third mask layer may include, for example, a photoresist layer or one or more of a spin-on-hardmask (SOH) or amorphous carbon layer (ACL) in addition to the photoresist layer.

The third mask layer may be patterned to form a third mask 930, and the first and second insulating interlayers may be etched using the third mask 930 as an etching mask to form first and second insulating interlayer patterns 910 and 920, respectively.

A fifth opening 940 may be formed through the first and second insulating interlayer patterns 910 and 920 to expose an upper surface and an upper sidewall of the second metal pattern 745 and upper surfaces of the second barrier pattern 735, the spacer structure 660 and the first capping pattern 585. In some example embodiments, a plurality of fifth openings 940 may be formed to be spaced apart from each other in the first and second directions D1 and D2, and may be arranged in a honeycomb pattern in a plan view. Each of the fifth openings 940 may have a shape of a circle, an ellipse, a polygon such as a rectangle and/or a hexagon that is chamfered and/or beveled, etc., in a plan view.

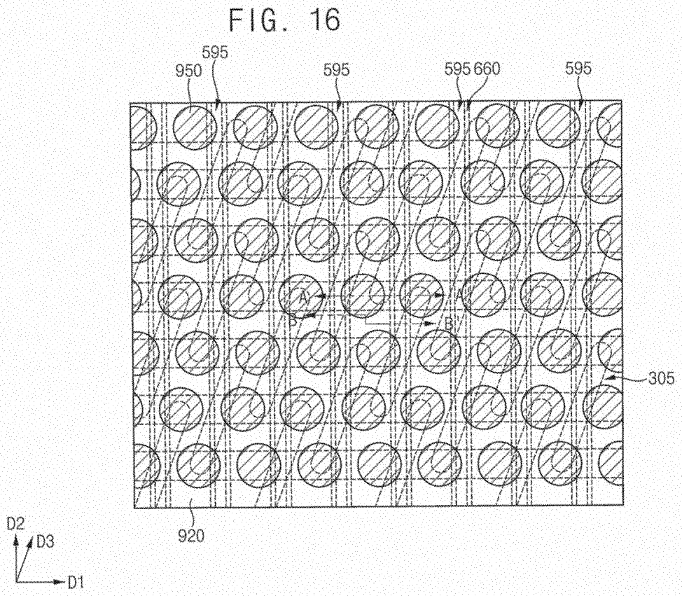

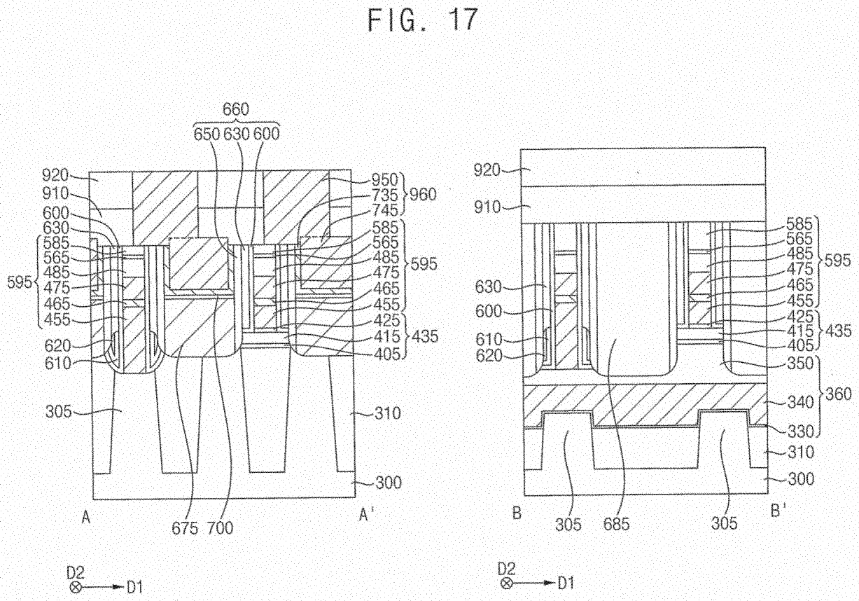

Referring to FIGS. 16 and 17, a third metal pattern 950 may be formed to fill the fifth opening 940.

The third metal pattern 950 may be formed by forming a third metal layer on the upper surface and the upper sidewall of the second metal pattern 745, the upper surfaces of the second barrier pattern 735, the spacer structure 660 and the first capping pattern 585 and the second insulating interlayer pattern 920 to fill the fifth opening 940, and planarizing the third metal layer until an upper surface of the second insulating interlayer pattern 920 is exposed.

The third metal pattern 950 may be formed in the fifth opening 940, and thus may have a shape substantially the same as the shape of the fifth opening 940. Additionally or alternatively, the third metal patterns 950 may have an arrangement substantially the same as the arrangement of the fifth openings 940. For example, the third metal pattern 950 may have a shape of a circle, an ellipse, a polygon such as a quadrilateral and/or a hexagon and/or a chamfered or beveled polygon, etc., in a plan view, and the third metal patterns 950 may be spaced apart from each other in the first and second directions D1 and D2 in a honeycomb pattern in a plan view.

The second metal pattern 745, the second barrier pattern 735 and the third metal pattern 950 may form an upper contact plug, and the lower contact plug 675, the metal silicide pattern 700 and the upper contact plug 960 sequentially stacked on the substrate 300 may form a contact plug structure.

In some example embodiments, the second and third metal patterns 745 and 950 may include substantially the same metal to be merged with each other. Alternatively, the second and third metal patterns 745 and 950 may include different metals from each other and/or may not include the same metal as each other, or may include substantially the same metal, however, may be differentiated from each other, for example due to a natural oxide layer or native oxide layer therebetween.

If the second spacer 630 is removed to form the air gap, a top end of the air gap may be covered by the first insulating interlayer pattern 910 and/or the third metal pattern 950 to form an air spacer.

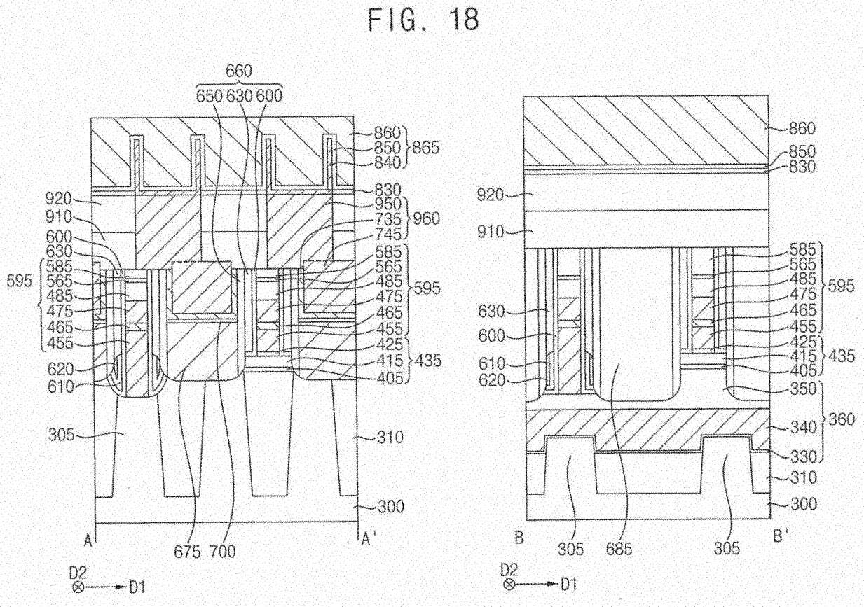

Referring to FIG. 18, a memory component or unit such as a capacitor 865 and/or a memristor may be formed to contact an upper surface of the upper contact plug 960.

For example, a second etch stop layer 830 and a mold layer may be sequentially formed on the upper contact plug 960 and the second insulating interlayer pattern 920, and may be partially etched to form sixth opening partially exposing an upper surface of the upper contact plug 960. The second etch stop layer 830 may include, for example, one or more of silicon boron nitride, silicon carbonitride, etc.

A lower electrode layer may be formed on a sidewall of the sixth opening, the exposed upper surface of the upper contact plug 960 and the mold layer, a sacrificial layer may be formed on the lower electrode layer to fill the sixth opening, and the lower electrode layer and the sacrificial layer may be planarized until an upper surface of the mold layer is exposed to divide the lower electrode layer.

The sacrificial layer and the mold layer may be removed by, e.g., a wet etching process using, e.g., LAL solution and/or a buffered oxide etch (BOE) solution, and thus a lower electrode 840 having a shape of a cylinder may be formed on the exposed upper surface of the upper contact plug 960. Alternatively or additionally, the lower electrode 840 having a pillar shape may be formed in the sixth opening. The lower electrode 840 may include, for example, a metal, a metal nitride, a metal nitride, doped polysilicon, etc.

A dielectric layer 850 may be formed on a surface of the lower electrode 840 and the second etch stop layer 830, and an upper electrode 860 may be formed on the dielectric layer 850 to form the capacitor 865 including the lower electrode 840, the dielectric layer 850 and the upper electrode 860

The dielectric layer 850 may include, for example, a metal oxide, and the upper electrode 860 may include, for example, a metal, a metal nitride, a metal silicide, doped polysilicon, etc.

Upper insulating interlayers, upper wirings, etc., may be further formed on the capacitor 865 to complete the fabrication of the semiconductor device.

As illustrated above, the upper contact plug 960 may be formed by forming the second barrier layer 730 and the second metal layer 740 on the bit line structure 595, the spacer structure 660 and the metal silicide pattern 700, planarizing the second barrier layer 730 and the second metal layer 740 until the upper surfaces of the bit line structure 595 and the spacer structure 660 are exposed to form the second barrier pattern 735 and the second metal pattern 745, removing the upper portions of the bit line structure 595, the spacer structure 660 and the second barrier pattern 735 to expose the upper sidewall of the second metal pattern 745, and forming the third metal pattern 950 to contact the exposed upper surface and the upper sidewall of the second metal pattern 745 by a damascene process.

The third metal pattern 950 may be formed by forming the first and second insulating interlayers 910 and 920, forming the fifth opening 940 through the first and second insulating interlayers 910 and 920 to expose the upper surface and the upper sidewall of the second metal pattern 745, and filling the fifth opening 940, and thus the third metal pattern 950 may contact the upper sidewall of the second metal pattern 745 in addition to the upper surface of the second metal pattern 745. Accordingly, an area of the second metal pattern 745 contacting the third metal pattern 950 may increase and/or a resistance therebetween may decrease.

For example, if the upper contact plugs are formed by forming the second barrier layer 730 and the second metal layer 740, partially etching the second barrier layer 730 and the second metal layer 740, and forming landing pads for contacting the capacitor 865 on pillar structures including the bit line structures 595 and the spacer structures 660 on the sidewalls of the bit line structures 595, the distances between the pillar structures are so small, and thus the upper contact plugs may not be formed to be sufficiently spaced apart from each other by an etching process. For example, the second barrier layer 730 and the second metal layer 740 have to be sufficiently etched in order that the upper contact plugs may not be connected with each other but may be sufficiently spaced apart from each other. However, portions of the second barrier layer 730 and the second metal layer 740 between neighboring pillar structures may be entirely removed so that an upper portion of the upper contact plug 675 for forming the landing pads and a lower portion of the upper contact plugs 675 on the lower contact plug 675 may not be connected with each other.

However, in some example embodiments, the upper contact plugs 960 may be formed by forming the third metal pattern 950 to contact the upper surface and the upper sidewall of the second metal pattern 745 by a damascene process, so that the third metal pattern 950 serving as the landing pad and the second metal pattern 745 on the lower contact plug 675 may not be spaced apart from each other but may be connected (e.g. directly connected) with each other.

The semiconductor device may include various structural characteristics such as the following non-limiting structural characteristics.

For example, the semiconductor device may include the active pattern 305 on the substrate 300, the gate structure 360 extending in the first direction D1 and buried at an upper portion of the active pattern 305; the bit line structure 595 extending in the second direction D2 on a central portion of the active pattern 305; the spacer structure 660 on the sidewall of the bit line structure 595; the contact plug structure on each of opposite end portions of the active pattern 305; and the capacitor 865 on the contact plug structure.

In some example embodiments, the contact plug structure may include the lower contact plug 675; the metal silicide pattern 700 on the lower contact plug 675; the second barrier pattern 735 on the metal silicide pattern 700; the second metal pattern 745 of which a lower surface and a lower sidewall are covered by the second barrier pattern 735; and the third metal pattern 950 contacting the upper surface and the upper sidewall of the second metal pattern 745 and the upper surfaces of the bit line structure 595 and the spacer structure 660.

In some example embodiments, an upper surface of the second metal pattern 745 may be higher than or above an upper surface of the bit line structure 595.

In some example embodiments, the active pattern 305 may extend in the third direction D3, and a plurality of active patterns 305 may be spaced apart from each other in the first and second directions D1 and D2. A plurality of gate structures 360 may be spaced apart from each other in the second direction D2, and a plurality of bit line structures 595 may be spaced apart from each other in the first direction D1.

In some example embodiments, a plurality of contact plug structures may be spaced apart from each other in the first and second directions D1 and D2, and may be arranged in a honeycomb pattern in a plan view.

In some example embodiments, an upper surface of the second metal pattern 745 may be substantially flat.

In some example embodiments, an upper surface of the second barrier pattern 735 may have a constant height.

In some example embodiments, the bit line structure 595 may include the conductive structure and the insulation structure stacked on the substrate 300. The conductive structure may include the first conductive pattern 455, the first barrier pattern 465 and the second conductive pattern 475, and the insulation structure may include the first mask 485, the first etch stop pattern 565 and the first capping pattern 585.

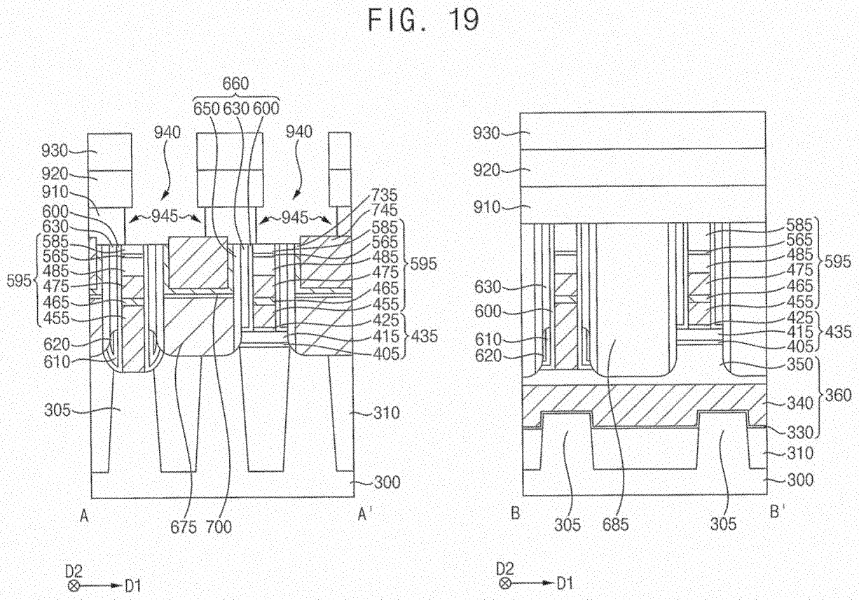

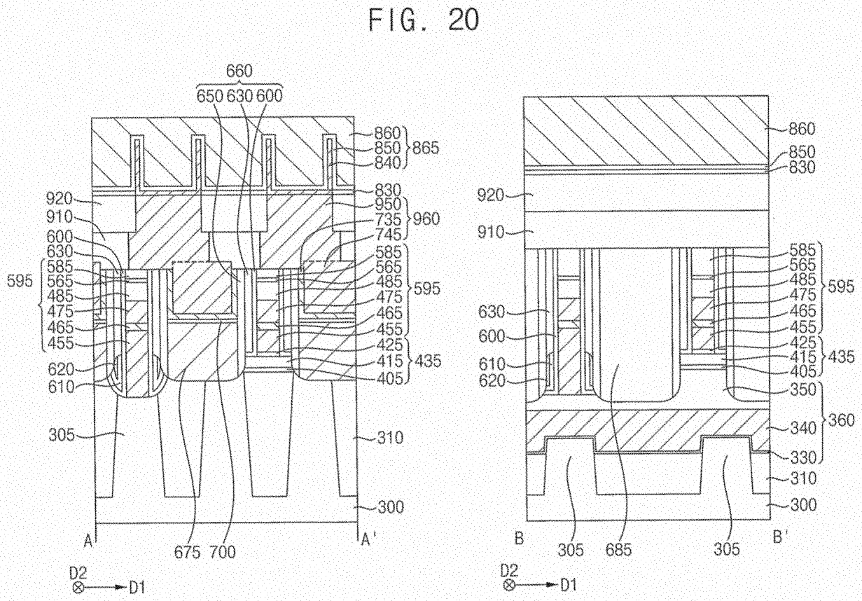

FIGS. 19 and 20 are cross-sectional views illustrating a method of manufacturing a semiconductor device in accordance with some example embodiments. This method may include processes substantially the same as or similar to those illustrated with reference to FIGS. 1 to 18, and thus repeated explanations thereof are omitted herein.

Referring to FIG. 19, processes substantially the same as or similar to those illustrated with reference to FIGS. 1 to 15 may be performed, and a lateral portion of the first insulating interlayer pattern 910 may be partially removed to enlarge a lower portion of the fifth opening 940, so that a third recess 945 connected to the fifth opening 940 may be formed.

The third recess 945 may be formed by, for example, a dry etching process and/or a wet etching process.

As the third recess 945 is formed to enlarge the lower portion of the fifth opening 940, an area of the upper surface of the second metal pattern 745 exposed by the fifth opening 940 may increase, and an area of the upper surfaces of the spacer structure 660 and the first capping pattern 585 adjacent to the second metal pattern 745 exposed by the fifth opening 940 may also increase.

Referring to FIG. 20, processes substantially the same as or similar to those illustrated with reference to FIGS. 16 to 18 may be performed to complete the fabrication of the semiconductor device.

When the processes illustrated with reference to FIGS. 16 to 17 are performed to form the third metal pattern 950, the area of the upper surface of the second metal pattern 745 exposed by the fifth opening 940 has increased, and thus the area of the third metal pattern 950 contacting the second metal pattern 745 may increase and/or resistance therebetween may decrease.

Additionally, the area of the upper surfaces of the spacer structure 660 and the first capping pattern 585 adjacent to the second metal pattern 745 exposed by the fifth opening 940 has increased, and thus a failure in which a lower portion of the third metal pattern 950 does not contact the upper sidewall of the second metal pattern 745 may be prevented or reduced in likelihood of occurrence and/or impact from occurrence.

In the semiconductor device, the third metal pattern 950 of the upper contact plug may include an upper portion having a first width and a lower portion having a second width greater than the first width. Thus, the area of the third metal pattern 950 contacting the second metal pattern 745 may increase and/or resistance therebetween may decrease, and may be well connected to the second metal pattern 745 even if misalignment occurs.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While inventive concepts have been shown and described with reference to some example embodiments thereof, it will be understood by those of ordinary skill in the art that various changes in form and details may be made thereto without departing from the spirit and scope of example embodiments as set forth by the following claims. Furthermore example embodiments are not necessarily mutually exclusive with one another. For example, some example embodiments may include one or more features described with reference to one or more figures, and may also include one or more other features described with reference to one or more other figures.

What is claimed is:

1. A semiconductor device comprising:
a bit line structure on a substrate;
a lower contact plug on a portion of the substrate that is adjacent to the bit line structure;
an upper contact plug including,
a first metal pattern on the lower contact plug, and
a second metal pattern contacting an upper surface and an upper sidewall of the first metal pattern; and
a capacitor on the upper contact plug,
wherein the upper surface of the first metal pattern is above an upper surface of the bit line structure with respect to an upper surface of the substrate.

2. The semiconductor device according to claim 1, wherein the upper surface of the first metal pattern is flat.

3. The semiconductor device according to claim 1, further comprising:
a barrier pattern covering a lower surface of and a lower sidewall of the first metal pattern.

4. The semiconductor device according to claim 3, wherein a lower surface of the second metal pattern contacts an upper surface of the barrier pattern.

5. The semiconductor device according to claim 3, wherein the upper surface of the barrier pattern has a constant height.

6. The semiconductor device according to claim 1, further comprising:
a spacer structure on a sidewall of the bit line structure,
wherein a lower surface of the second metal pattern contacts the upper surface of the bit line structure and an upper surface of the spacer structure.

7. The semiconductor device according to claim 1, wherein the second metal pattern has an upper portion having a first width and a lower portion having a second width greater than the first width.

8. The semiconductor device according to claim 1, wherein the bit line structure includes a conductive structure and an insulation structure that are stacked on the substrate.

9. A semiconductor device comprising:
a bit line structure on a substrate;
a lower contact plug on a portion of the substrate that is adjacent to the bit line structure;
an upper contact plug including,
a first metal pattern on the lower contact plug,
a barrier pattern covering a lower surface and a lower sidewall of the first metal pattern, and
a second metal pattern contacting an upper surface and an upper sidewall of the first metal pattern and an upper surface of the barrier pattern; and
a capacitor on the upper contact plug,
wherein the upper surface of the barrier pattern is planar.

10. The semiconductor device according to claim 9, wherein the upper surface of the first metal pattern is flat.

11. The semiconductor device according to claim 9, further comprising:
a spacer structure on a sidewall of the bit line structure,
wherein a lower surface of the second metal pattern contacts an upper surface of the bit line structure and an upper surface of the spacer structure.

12. The semiconductor device according to claim 9, wherein the second metal pattern has an upper portion having a first width and a lower portion having a second width greater than the first width.

13. The semiconductor device according to claim 9, wherein an upper surface of the first metal pattern is above an upper surface of the bit line structure with respect to an upper surface of the substarte.

14. The semiconductor device according to claim 9, wherein the bit line structure includes a conductive structure and an insulation structure that are stacked on the substrate.

15. A semiconductor device comprising:
an active pattern on a substrate;
a gate structure buried in an upper portion of the active pattern, the gate structure extending in a first direction that is parallel to an upper surface of the substrate;
a bit line structure on a central upper surface of the active pattern and extending in a second direction that is parallel to the upper surface of the substrate and perpendicular to the first direction;
a spacer structure on a sidewall of the bit line structure;
a contact plug structure on each of opposite end portions of the active pattern; and
a capacitor on the contact plug structure,
wherein the contact plug structure includes,
a lower contact plug,
a metal silicide pattern on the lower contact plug,
a barrier pattern on the metal silicide pattern,
a first metal pattern of which a lower surface and a lower sidewall are covered by the barrier pattern; and
a second metal pattern contacting an upper surface of and an upper sidewall of the first metal pattern and upper surfaces of the bit line structure and the spacer structure, and
wherein the upper surface of the first metal pattern is above the upper surface of the bit line structure with respect to an upper surface of the substrate.

16. The semiconductor device according to claim 15, wherein the active pattern is one of a plurality of active patterns that are spaced apart from each other in the first and second directions, each of the plurality of active patterns extending in a third direction parallel to the upper surface of the substrate and having an acute angle with the first and second directions, and
the gate structure is one of a plurality of gate structures that are spaced apart from each other in the second direction, and the bit line structure is one of a plurality of bit line structures that are spaced apart from each other in the first direction.

17. The semiconductor device according to claim 16, wherein the contact plug structure is one of a plurality of contact plug structures that are spaced apart from each other in the second direction, the plurality of contact plug structures arranged in a honeycomb pattern in a plan view.

18. The semiconductor device according to claim 15, wherein the upper surface of the first metal pattern is flat.

19. The semiconductor device according to claim 15, wherein the upper surface of the barrier pattern has a constant height.

20. The semiconductor device according to claim 15, wherein the second metal pattern has an upper portion having a first width and a lower portion having a second width greater than the first width.
